(19) United States
(12) Patent Application Publication
(10) Pub. No.: US 2025/0311173 A1
(43) Pub. Date: Oct. 2, 2025

(54) LIQUID COOLING CONTROL METHOD AND LIQUID COOLING COMPUTING DEVICE

(71) Applicant: Lenovo Enterprise Solutions (Singapore) Pte. Ltd., Singapore (SG)

(72) Inventors: Cheng Hsiung HUNG, Singapore (SG); Sean HSU, Singapore (SG); Chun Hsiang CHOU, Singapore (SG); Chih Pao CHANG, Singapore (SG); Maoyuan LIN, Singapore (SG); Hsin-Shou CHEN, Singapore (SG)

(21) Appl. No.: 19/094,580

(22) Filed: Mar. 28, 2025

(30) Foreign Application Priority Data
Apr. 1, 2024 (CN) 202410389844.3

(51) Int. Cl. H05K 7/20

(52) U.S. Cl. CPC H05K 7/20836; H05K 7/20272; H05K 7/20281; H05K 7/20781

(57) ABSTRACT

A liquid cooling control method including using a baseboard management controller (BMC) of a first monitored object in a liquid cooling computing device to obtain a plurality of first operating parameters of each monitored object at a first time; and controlling a cooling unit in the liquid cooling computing device to adjust a flow rate and/or temperature of coolant through the BMC of the first monitored object based on the plurality of first operating parameters of each of the monitored objects, the first operating parameter characterizing the temperature of the monitored object, and the monitored object including at least one server chassis in the liquid cooling computing device and at least one server located on each server chassis, the first monitored object being one of all monitored objects.

### CROSS-REFERENCES TO RELATED APPLICATION

This application claims priority to Chinese Patent Application No. 202410389844.3 filed on Apr. 1, 2024, the entire content of which is incorporated herein by reference.

### FIELD OF TECHNOLOGY

The present disclosure relates to the field of computer technology and, more specifically, to a liquid cooling control method and a liquid cooling computing device.

### BACKGROUND

With the development of computer technology, liquid cooling computing devices containing multiple servers are adopting a more sophisticated integrated chip architecture to improve computing performance, which will also lead to a rapid increase in server power density. Conventional air-cooling technology is no longer the best choice. Liquid cooling technology uses coolants to directly dissipate heat from the server or chip, eliminating the need for air cooling in the middle, resulting in higher heat dissipation efficiency.

At present, in the design of liquid cooling, the liquid-cooling computing device includes a coolant distribution unit (CDU), and the CDU independently controls its own operating states. The user determines the temperature and flow rate of the coolant in the CDU based on the number of servers included in the liquid-cooling computing device, and then the user manually configures it on the display interface of the CDU to cool down the servers of the liquid-cooling computing device. However, when the temperature of a server is abnormal, the user must manually re-adjust the temperature and flow rate of the coolant in the CDU. This process is inefficient and complicated.

### SUMMARY

One aspect of this disclosure provides a liquid cooling control method. The liquid cooling control method includes using a baseboard management controller (BMC) of a first monitored object in a liquid cooling computing device to obtain a plurality of first operating parameters of each monitored object at a first time; and controlling a cooling unit in the liquid cooling computing device to adjust a flow rate and/or temperature of coolant through the BMC of the first monitored object based on the plurality of first operating parameters of each of the monitored objects. The first operating parameter characterizes the temperature of the monitored object, and the monitored object includes at least one server chassis in the liquid cooling computing device and at least one server located on each server chassis, the first monitored object being one of all monitored objects.

Another aspect of this disclosure provides a liquid cooling computing device. The liquid cooling computing device includes a processor, a memory storing program instructions, and a communication bus. The communication bus is used to establish a communication connection between the processor and the memory. The program instructions stored in the memory, when being executed by the processor, cause the processor to use a baseboard management controller (BMC) of a first monitored object in the liquid cooling computing device to obtain a plurality of first operating parameters of each monitored object at a first time; and control a cooling unit in the liquid cooling computing device to adjust a flow rate and/or temperature of coolant through the BMC of the first monitored object based on the plurality of first operating parameters of each of the monitored objects. The first operating parameter characterizes the temperature of the monitored object, and the monitored object includes at least one server chassis in the liquid cooling computing device and at least one server located on each server chassis, the first monitored object being one of all monitored objects.

Another aspect of this disclosure provides a liquid cooling control device. The liquid cooling computing device includes an acquisition module and a control module. The acquisition module is configured to use a baseboard management controller (BMC) of a first monitored object in a liquid cooling computing device to obtain a plurality of first operating parameters of each monitored object at a first time. The control module is configured to control a cooling unit in the liquid cooling computing device to adjust a flow rate and/or temperature of coolant through the BMC of the first monitored object based on the plurality of first operating parameters of each of the monitored objects.

### BRIEF DESCRIPTION OF THE DRA WINGS

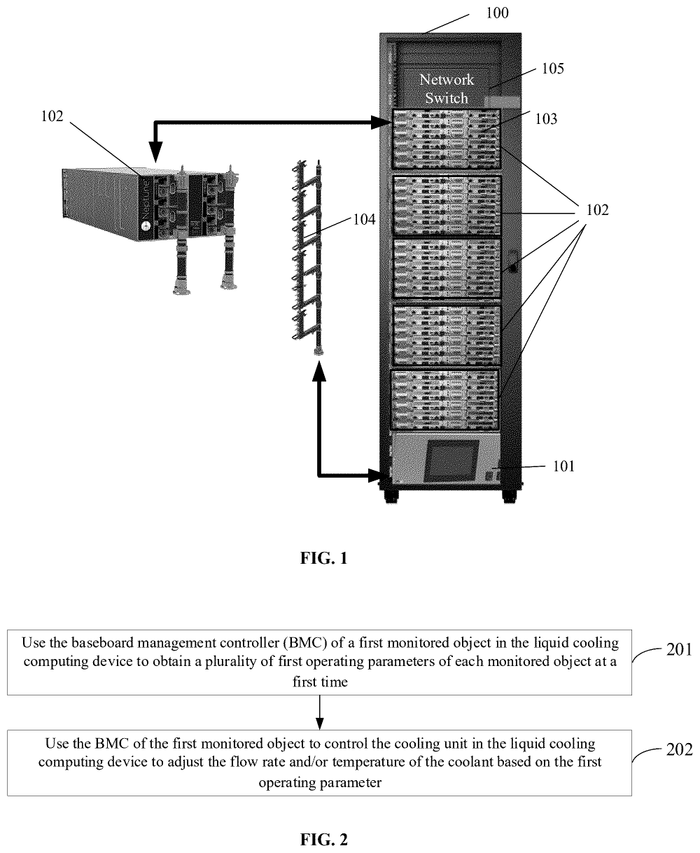

FIG. 1 is a schematic diagram of an application scenario of a liquid cooling control method according to some embodiments of the present disclosure.

FIG. 2 is a flowchart of the liquid cooling control method according to some embodiments of the present disclosure.

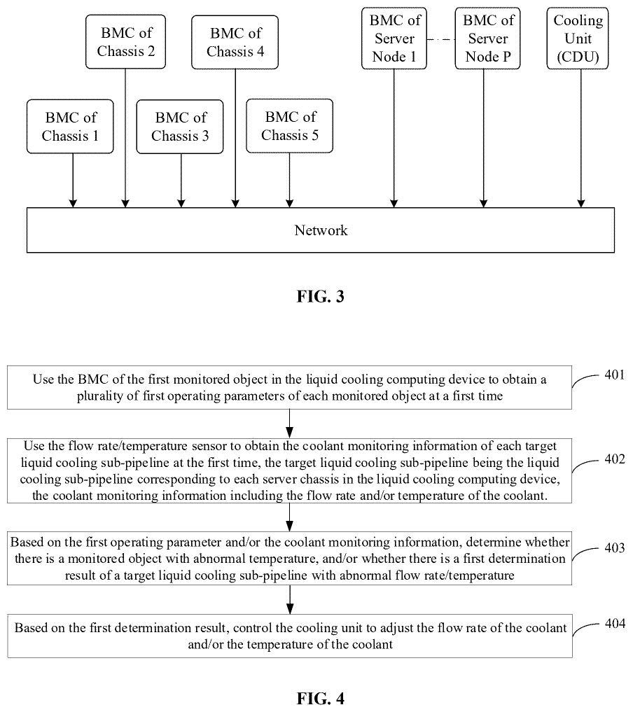

FIG. 3 is a schematic diagram of a baseboard management controller (BMC) and a coolant distribution unit (CDU) communicating via a network according to some embodiments of the present disclosure.

FIG. 4 is a flowchart of the liquid cooling control method according to some embodiments of the present disclosure.

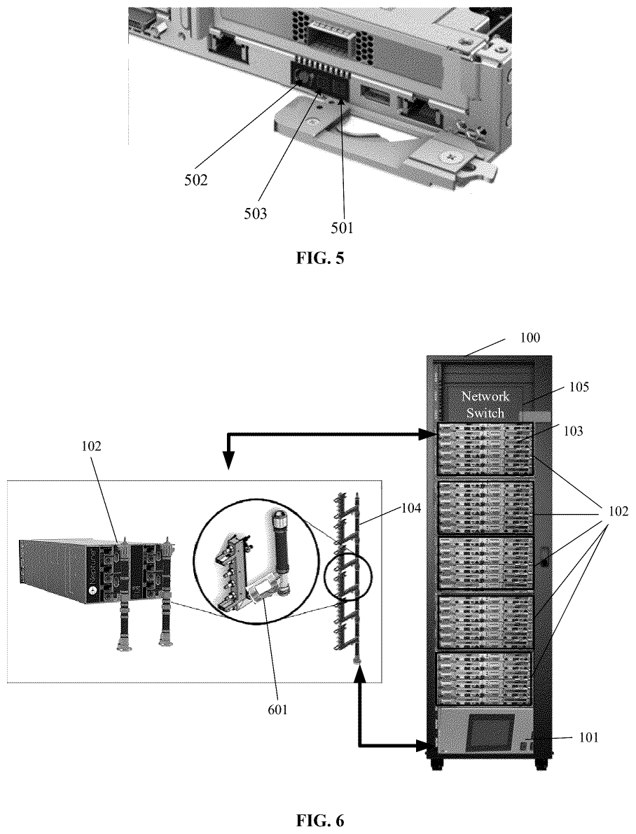

FIG. 5 is a schematic diagram of a scenario of an indicator light prompt of a monitored object according to some embodiments of the present disclosure.

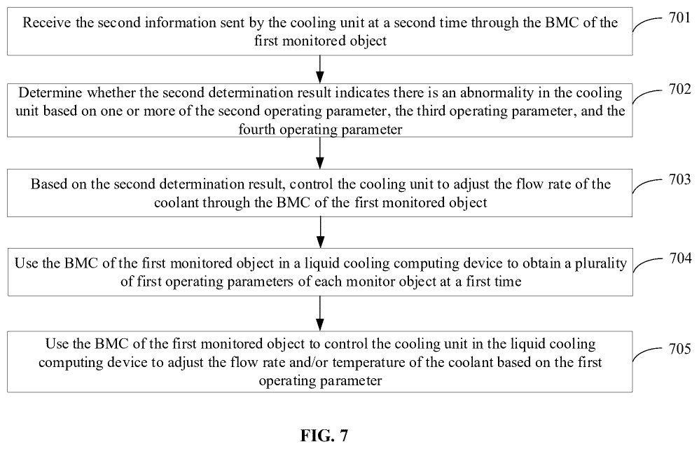

FIG. 6 is a schematic diagram of a scenario in which a flow rate and temperature of a coolant flowing into each server chassis are monitored by a flow rate/temperature sensor according to some embodiments of the present disclosure.

FIG. 7 is a flowchart of the liquid cooling control method according to some embodiments of the present disclosure.

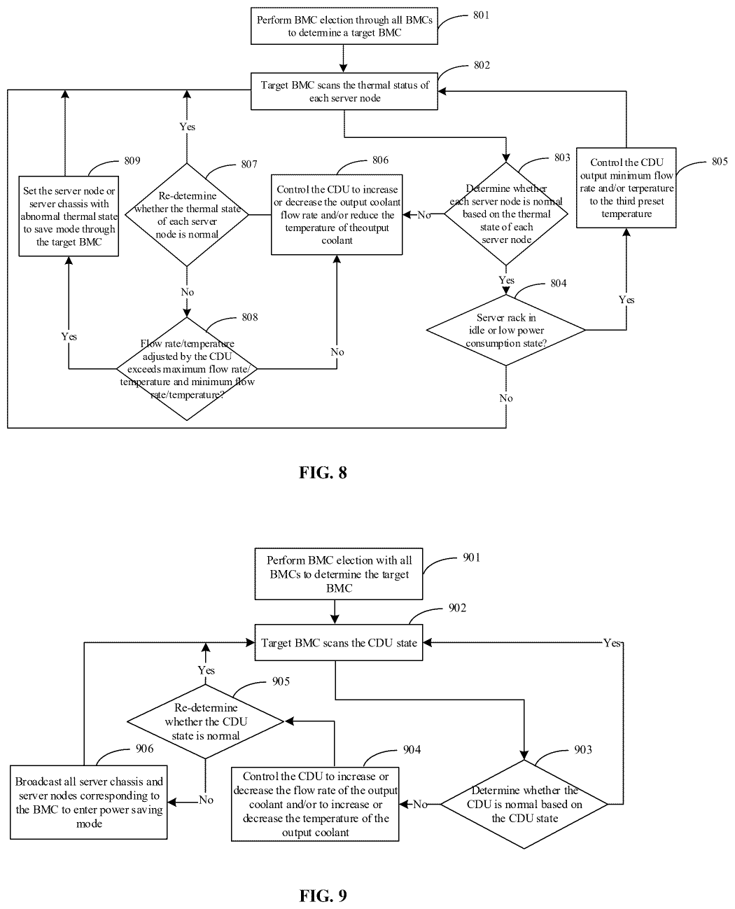

FIG. 8 is a flowchart of the liquid cooling control method according to some embodiments of the present disclosure.

FIG. 9 is a flowchart of the liquid cooling control method according to some embodiments of the present disclosure.

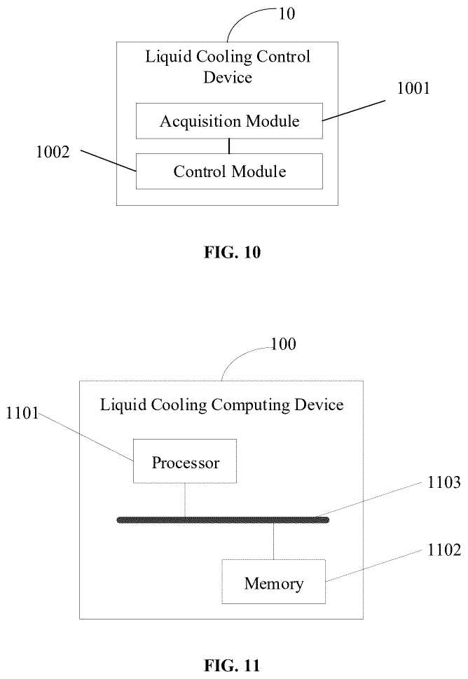

FIG. 10 is a schematic structural diagram of a liquid cooling control device according to some embodiments of the present disclosure.

FIG. 11 is a schematic structural diagram of a liquid cooling computing device according to some embodiments of the present disclosure.

### DETAILED DESCRIPTION

Technical solutions of the present disclosure will be described in detail with reference to the drawings. It will be appreciated that the embodiments described represent some, rather than all, of the embodiments of the present disclosure. Other embodiments conceived or derived by those having ordinary skills in the art based on the described embodiments without inventive efforts should fall within the scope of the present disclosure.

The terms “first,” “second,” or the like in the specification, claims, and the drawings of the present disclosure are merely used to distinguish similar elements, and are not intended to describe a specified order or a sequence. The elements involved may be interchangeable in any suitable situation, so that the present disclosure can be performed in the order or sequence different from that shown in the figures or described in the specification. In addition, the terms “including,” “comprising,” and variations thereof herein are open, non-limiting terminologies, which are meant to encompass a series of steps of processes and methods, or a series of units of systems, apparatus, or devices listed thereafter and equivalents thereof as well as additional steps of the processes and methods or units of the systems, apparatus, or devices.

Reference herein to an “embodiment” means that a particular feature, structure, or characteristic described in connection with the embodiment can be included in at least one embodiment of the present disclosure. The occurrences of the phrase in various places in the specification are not necessarily all referring to the same embodiment, nor are separate or alternative embodiments mutually exclusive of other embodiments. It is understood explicitly and implicitly by those skilled in the art that the embodiments described herein can be combined with other embodiments.

To better understand the technical solutions of the present disclosure, the relevant technologies of the liquid cooling control method provided by the present disclosure are explained below.

Since the CDU independently controls its own operating state, first, the number of servers contained in the liquid colling computing device is determined. For example, the number of servers contained in the server rack is 60. Based on the number of servers and the predetermined flow rate required for a single server node, such as 2 liters/minute (L/min, or L/M) and temperature, such as 40 degrees Celsius (° C.), the flow rate of the coolant in the CDU is determined to be 90 to 160 L/min and the temperature is 20 to 50° C. The user can then manually configure the CDU display interface to cool down the servers in the liquid cooling computing device. However, when the temperature of a server is abnormal, the user must manually readjust the temperature and flow rate of the coolant in the CDU. This method is inefficient and complicated.

Based on the above description, FIG. 1 is a schematic diagram of an application scenario of a liquid cooling control method according to some embodiments of the present disclosure.

As shown in FIG. 1, the liquid cooling control method provided by the embodiments of the present disclosure can be applied to a liquid cooling computing device (also referred to as a server rack) 100, which includes a cooling unit (also referred to as a CDU) 101 and a plurality of server chassis 102. A plurality of servers 103 may be configured in each server chassis 102, and the server chassis 102, the servers 103 and the cooling unit 101 communicate with each other via a network switch 105. The cooling unit 101 is connected to the plurality of server chassis 102 and servers in the server chassis on the liquid cooling computing device 100 through a manifold 104. A liquid cooling computing device 100 may be configured with a cooling unit, and each server chassis may correspond to a manifold.

In the embodiments of the present disclosure, the coolant flowing out of the liquid outlet of the cooling unit 101 is distributed to each server chassis 102 in the liquid cooling computing device 100 and the CDU cold plate of the server through the cooling unit 101 to meet the coolant flow demand. The liquid flow on the CDU cold plate is then passed through the CDU for heat exchange with repeated circulation to ensure that the liquid inlet temperature of the cold plate is stable within a reasonable range.

Embodiments of the present disclosure provide a liquid cooling control method. FIG. 2 is a flowchart of the liquid cooling control method according to some embodiments of the present disclosure. The method will be described in detail below.

201, using a baseboard management controller (BMC) of a first monitored object in the liquid cooling computing device to obtain a plurality of first operating parameters of each monitored object at a first time.

In some embodiments, the first operating parameter may characterize the temperature of the monitored objects. The monitored objects may include at least one server chassis in the liquid cooling computing device, and at least one server located on each server chassis, and the first monitored object may be one of the monitored objects.

In some embodiments, the liquid cooling computer device may include a server chassis and a server. The server chassis may be a physical structure that houses and organizes at least one server and its internal components such as the motherboard, CPU, memory, hard disk, power supply unit (PSU), fans, and other expansion cards and I/O interfaces. It should be noted that the design of the server chassis takes into account factors such as high availability, heat dissipation efficiency, maintainability and standardization in order to adapt to the needs of the data center room, such as easy deployment to the rack, good heat dissipation capacity and redundant power supply options.

In some embodiments, each server chassis or the motherboard of a single server may be equipped with a baseboard management controller (BMC), which enables detailed monitoring of the entire system and its internal components. The BMC is the core component of server hardware management. As a microcomputer system independent of the server operating system and hardware resources, BMC has its own microprocessor, memory and storage space.

In some embodiments, the server chassis may be equipped with a system management mode (SMM) with hardware-level management. The functions provided by the SMM can work closely with various hardware subsystems inside the server chassis, such as monitoring and controlling the temperature, fan speed, power status, etc. inside the chassis. The SMM can work with the server motherboard and other management controllers in the chassis to ensure the health of the entire server system and the effective use of resources. Therefore, the normal operation and management of the server chassis cannot be separated from the underlying system management support provided by the SMM. It should be noted that the SMM is substantially also a type of BMC. For example, as shown in FIG. 1, a server chassis includes BMCs for 12 server nodes and one SMM (i.e., chassis BMC), and the liquid cooling computing device has five server chassis. In this case, the liquid cooling computing device has a total of 65 BMCs, including the BMCs of the server nodes and the BMCs of the server chassis, and is provided with six manifolds.

It should be noted that the BMC of each monitored object and the cooling unit may be connected to the same network, and each BMC and cooling unit may communicate through a network switch and transmit the real-time operating parameters of each monitored object. Referring to FIG. 1 and FIG. 3, the five chassis BMCs, the BMC of the server node, and the cooling unit CDU are communicated with each other through a network.

In some embodiments, the BMC can monitor the temperature (which is a hardware state) of each monitored object. The BMC can monitor the temperature of the central processing unit (CPU), the temperature of the graphics processing unit (GPU), the temperature of the dual-inline-memory-modules (DIMM), the temperature of the hard drive, and the ambient temperature around the monitored objects. Of course, the BMC can also monitor other hardware states of each monitored object, including but not limited to voltage, fan speed, power state, hard disk state, hard disk usage, CPU usage and other basic information required for the normal operation of the server or server chassis.

In some embodiments, the first monitored object may be used to control the cooling unit through the BMC. The first monitored object can be understood as the leading monitored object. The first monitored object can be any one of the monitored objects. Since the cooling unit can only be controlled by the BMC of the first monitored object, there is a need to first determine the first monitored object. In the embodiments of the present disclosure, the monitored object may be determined in the following manners.

In the first method, the BMCs of each monitored object can select a BMC through an election method, and the monitored object corresponding to the selected BMC can be determined as the first monitored object. For example, the BMCs of all monitored objects can run the election function to elect a BMC such that the monitored object corresponding to the elected BMC is the first monitored object. At the same time, other BMCs can synchronize the real-time operating parameters of all hardware devices of the corresponding monitored objects obtained by their respective BMCs to the elected BMC.

In the second method, a BMC can be designated among the BMCs of the plurality of monitored objects, and the monitored object corresponding to the designated BMC can be determined as the first monitored object.

In some embodiments, the first operating parameter may be a parameter that can characterize the temperature of the monitored object. The first operating parameter may include but is not limited to the temperature of the CPU and/or GPU of the monitored object, the occupancy rate of the CPU and/or GPU of the monitored object, the power consumption of the CPU and/or GPU of the monitored object, etc. It should be noted that other parameters can also be used as the first type of operating parameters of the monitoring object. For example, multiple temperature collection points can be configured on the monitored object, and the weight of the temperature collected by each temperature collection point can be determined. Subsequently, the temperature of the monitored object can be determined based on the temperature values collected by the multiple temperature collection points and the weight of the temperature of each temperature collection point. Similarly, other parameters may be set as the first type of operating parameters of the monitored object based on actual needs, which is not limited in the embodiments of the present disclosure.

In some embodiments, the liquid cooling computing device may use the BMC of the first monitored object to obtain the first operating parameter of each monitored object at a first time that can characterize the temperature of the monitored object. The monitored objects may include at least one server chassis in the liquid-cooling computing device and at least one server located on each server chassis.

202, using the BMC of the first monitored object to control the cooling unit in the liquid cooling computing device to adjust the flow rate and/or temperature of the coolant based on the first operating parameter.

The cooling unit (CDU) is an important component for efficient heat dissipation of liquid cooling computing devices. The cooling unit is used to accurately distribute the coolant to various computing devices in the liquid cooling computing device according to the preset strategy and needs, such as servers, storage devices or other electronic components that generate a lot of heat, to absorb and discharge the heat generated during the operation of the devices, thereby ensuring that the devices can work efficiently and stably at a constant and appropriate temperature.

Referring to FIG. 1, the cooling unit CDU generally has an advanced management system interface, allowing users to intuitively monitor and control various parameters and states of the cooling system. In addition, to facilitate remote management and automated operation and maintenance, CDU generally supports simple network management protocol (SNMP) and secure shell command line interface (SSH CLI) functions. Through these network interfaces, data center managers can remotely log in to the CDU to perform real-time monitoring, troubleshooting, parameter setting, and maintenance operations, which greatly improves the operation and maintenance efficiency and management level of the data center.

In some embodiments, after detecting the first operating parameters of each monitored object in real time, such as temperature, power consumption and other key information, through the BMC of the first monitored object, based on the first operating parameters obtained in real time, the liquid cooling computing device can dynamically adjust the cooling strategy of the cooling unit through the communication interface between the BMC of the first monitoring object and the cooling unit. The cooling strategy may include at least the coolant flow rate and the coolant temperature output by the cooling unit.

For the dynamic adjustment of coolant flow rate of the cooling unit, if the temperature of a monitored object is detected to be rising or abnormal, it may indicate that the heat generated by the monitored object has increased. At this time, the cooling unit can be controlled by the BMC to increase the flow rate of coolant flowing out of the liquid outlet of the cooling unit to enhance the cooling effect. On the contrary, when the temperature is relatively low, the cooling unit can be controlled by the BMC to appropriately reduce the flow of coolant flowing out of the liquid outlet of the cooling unit to save energy and avoid overcooling.

For the dynamic adjustment of coolant temperature, in some cases, the initial temperature of the coolant may also affect the cooling effect. If the internal temperature of the monitored object is relatively high or abnormal, in addition to increasing the coolant flow rate, the BMC can also be used to control the cooling unit to adjust the coolant temperature. In this way, the coolant temperature can be maintained at a lower level to improve the cooling efficiency.

In the embodiments of the present application, by accurately monitoring and automatically adjusting the flow rate and/or temperature of the coolant, precise on-demand cooling of the liquid cooling computing device can be realized, which not only ensures the safe and stable operation of the device, but also improves energy efficiency and reduces operating costs.

Consistent with the present disclosure, the BMC of the first monitored object in the liquid cooling computing device can be used to obtain a plurality of first operating parameters of each monitored object at a first time. The first operating parameter can characterize the temperature of the monitored object. The monitored object can include at least one server chassis in the liquid cooling computing device. At least one server can be located on each server chassis, and the first monitored object can be one of the monitored objects. In this way, the plurality of first operating parameters of all monitored objects (including at least one server chassis and at least one server thereon) can be obtained at the first time through the BMC of the first monitored object in the liquid cooling computing device. These parameters can accurately reflect the temperature state of the monitored objects. One of the monitored objects can be selected as the first monitored object such that the temperature and flow rate of the cooling unit can be managed through its BMC. Further, based on the first operating parameters of each monitored object, the BMC of the first monitored object can be used to control the cooling unit in the liquid cooling computing device to adjust the flow rate and/or temperature of the cooling liquid. In this way, the flow rate and temperature of the coolant can be flexibly adjusted based on the real-time temperature feedback of each monitored object, thereby achieving efficient cooling of the data center, ensuring that key devices such as servers can operate stably at an appropriate temperature, and extending the life of the devices. At the same time, the cooling strategy can be adjusted dynamically to avoid unnecessary energy waste and improve energy utilization efficiency and processing efficiency, and real-time monitoring and intelligent adjustment can be performed to reduce the risk of system downtime due to overheating and improve the overall service availability of the data center.

Embodiments of the present disclosure provide a liquid cooling control method. This method can be applied to liquid cooling computing devices. FIG. 4 is a flowchart of the liquid cooling control method according to some embodiments of the present disclosure. The method will be described in detail below.

401, using the BMC of the first monitored object in the liquid cooling computing device to obtain a plurality of first operating parameters of each monitored object at a first time.

In some embodiments, the first operating parameter may characterize the temperature of the monitored objects. The monitored objects may include at least one server chassis in the liquid cooling computing device, and at least one server located on each server chassis, and the first monitored object may be one of the monitored objects.

In some embodiments, the process of using the BMC of the first monitored object in the liquid cooling computing device to obtain a plurality of first operating parameters of each monitored object at a first time at 401 may be implemented through the following processes.

410, responding to a first instruction and determining the first monitored object based on the first instruction.

In some embodiments, the first instruction may be used to indicate the monitored object, and the first instruction may carry an object identifier of the monitored object. When the liquid cooling computing device obtains the first instruction, the first monitored object corresponding to the object identifier may be determined based on the object identifier in the first instruction, thereby controlling the cooling unit through the first monitored object.

Referring to FIG. 5, in some embodiments, after the first monitored object is determined, the first monitoring object may generate an indicator light prompt message 501. The indicator light prompt message 501 may be used to prompt that the monitoring object is the first monitoring object, thereby prompting the operator to control the monitoring object of the cooling unit currently. The indicator light can be in different colors (such as green, yellow or red) or in different flashing patterns to distinguish it from other monitored objects. In this way, the data center operator can quickly identify the monitored object currently controlling the CDU such that when there is a communication breakdown between the first monitored object and the CDU, the operator can quickly locate the monitoring object. Of course, each monitored object may also have a power switch indicator light 502 and a positioning indicator light 503 for identifying and locating abnormalities of a specific monitored object. The power switch indicator light 502 can be used to indicate that the monitored object is in a working state, and the positioning indicator light 503 can be used to indicate when the monitored object has abnormal temperature. The abnormal information of the monitored object can be conveyed to the on-site operation and maintenance personnel by lighting or flashing the positioning identification indicator light 503.

411, obtaining a plurality of first operating parameters of the first monitored object at the first time through the BMC of the first monitored object.

412, receiving, through the BMC of the first monitored object, the plurality of first operating parameters obtained at the first time and sent by the BMC of at least one second monitored object.

In some embodiments, the second monitored object may be other monitored objects among all monitored objects except the first monitored object.

In actual applications, the BMC of each monitored object may obtain the first operating parameters of the corresponding monitored object at a first fixed time interval. Of course, the second monitored objects other than the first monitored object among all the monitored objects may also send the obtained first operating parameters to the BMC of the first monitored object at a second fixed time interval such that the BMC of the first monitored object can synchronize the real-time first operating parameters of each second monitored object.

Consistent with the present disclosure, in response to the first instruction, after determining the first monitored object based on the first instruction, a plurality of first operating parameters of the first monitored object at the first moment can be obtained through the BMC of the first monitored object, and the plurality of first operating parameters of the second monitored object at the first time can be obtained through the BMC of the second monitored object. Further, through the BMC of the first monitored object, the plurality of first operating parameters obtained at the first time and sent by the BMC of at least one second monitored object can be received. In this way, the BMC of the first monitored object can timely understand the temperature state of other monitored objects in the liquid cooling computing device to ensure the normal operation of the device and take cooling control measures when necessary to prevent failures caused by overheating.

In some embodiments, referring to FIG. 1 and FIG. 3, assuming that the server chassis on top of the liquid cooling computing device is the first monitored object, the SMM corresponding to the server chassis is used to ensure that the BMCs of all other monitored objects can access the latest configuration information and thermodynamic data to maintain consistency. In this architecture, the SMM of the top chassis acts as the master node, responsible for communicating with the BMCs on other chassis or servers to synchronize key system configuration and temperature data. The master control node collects the first operating parameters of all monitored objects, including but not limited to temperature, power status, fan speed, etc., to control the cooling unit. This ensures that all BMCs in the entire liquid cooling computing device operate based on the same set of latest configuration and thermal state data, avoiding potential risks caused by inconsistent data. In addition, global control is performed through a single master node, which simplifies the management difficulty of complex distributed systems and improves operation and maintenance efficiency.

402, using the flow rate/temperature sensor to obtain the coolant monitoring information of each target liquid cooling sub-pipeline at the first time, the target liquid cooling sub-pipeline being the liquid cooling sub-pipeline corresponding to each server chassis in the liquid cooling computing device, the coolant monitoring information including the flow rate and/or temperature of the coolant.

In some embodiments, a flow rate/temperature sensor 601 may be installed on the target liquid cooling sub-pipeline flowing to each server chassis. As shown in FIG. 6, the flow rate/temperature sensor is used to detect the flow rate and temperature of the coolant at the liquid inlet or outlet of each server chassis to determine whether the temperature and flow rate of the coolant flowing into the server chassis are normal. In some cases, the target liquid cooling sub-pipe may also be referred to as a manifold.

Consistent with the present disclosure, through the BMC of the first monitored object, the flow rate/temperature sensor can be used to obtain the coolant monitoring information of the target liquid cooling sub-pipe corresponding to each server chassis at the first time in real time. The monitoring information may include but is not limited to the flow rate and/or temperature of the coolant when it flows into or out of the server chassis. In this way, through real-time monitoring of coolant flow rate and temperature, the liquid cooling system of the data center can be managed in a refined manner, the cooling state of each server chassis can be accurately captured, and the cooling system can be ensured to match the server load to avoid overcooling or undercooling. At the same time, when abnormal coolant flow rate or high temperature is detected, early warning can be given and measures can be taken to prevent server failure due to overheating, which is beneficial to predictive maintenance and troubleshooting.

403, based on the first operating parameter and/or the coolant monitoring information, determining whether there is a monitored object with abnormal temperature, and/or whether there is a first determination result of a target liquid cooling sub-pipeline with abnormal flow rate/temperature.

In some embodiments, the first determination result may be a monitored object with abnormal temperature, a target liquid cooling sub-pipe with abnormal flow rate, or a target liquid cooling sub-pipe with abnormal temperature. Of course, the first determination result may also be a monitored object with a temperature anomaly and a target liquid cooling sub-pipeline with a flow rate/temperature anomaly, which is not limited in the embodiments of the present disclosure.

For the target liquid cooling sub-pipe corresponding to each server chassis, a first preset temperature range and a first preset flow rate range may be set. The first preset flow rate range may be determined based on the number of servers N included in each server chassis. If the flow required by a single server is 2L/M, the first preset flow rate range may be set in [2*N−10, 2*N+20], and the first preset temperature range may be [20, 50]. Of course, the first preset flow rate range and the first preset temperature range can also be set based on experience, which is not limited in the embodiments of the present disclosure.

In some embodiments, a second preset temperature range may be set for the first operating parameter of each monitored object, and the second preset temperature range may be a temperature range that affects the performance of components.

Consistent with the present disclosure, after obtaining the coolant monitoring information of the flow rate and/or temperature of the coolant included in each target liquid cooling sub-pipeline at the first time through the flow rate/temperature sensor, whether the first operating parameter used to characterize the temperature of the monitored object is within the second preset temperature range and whether the flow rate of the coolant contained in each target liquid cooling sub-pipeline is within the first preset flow rate range, or whether the temperature of the coolant contained in each target liquid cooling sub-pipeline is within the second preset temperature range can be determined. If one of the first operating parameter is within the second preset temperature range, the flow rate of the coolant included in each target liquid cooling sub-pipeline is not within the first preset flow rate range, or the temperature of the cooling liquid contained in each target liquid cooling sub-pipeline is within the second preset temperature range is met, the first determination result that a monitored object has a temperature anomaly and/or a target liquid-cooling sub-pipeline has a flow rate/temperature anomaly can be determined.

404, based on the first determination result, controlling the cooling unit to adjust the flow rate of the coolant and/or the temperature of the coolant.

In some embodiments, after the first determination result is obtained, the liquid cooling computing device may control the cooling unit to dynamically adjust the flow rate of the coolant output by the cooling unit and/or the temperature of the coolant based on the first determination result through the communication interface between the BMC of the first monitored object and the cooling unit. In this way, the flow and/or temperature of the coolant can be dynamically adjusted based on the actual cooling requirements of each server chassis in the liquid cooling computing device to reasonably allocate cooling resources.

In some embodiments, the process at 404, based on the first determination result, controlling the cooling unit to adjust the flow rate of the coolant and/or the temperature of the coolant, can be realized through the following steps.

Step A1, if the first determination result indicates that there is no monitored object with abnormal temperature, and/or there is no target liquid cooling sub-pipeline with abnormal flow rate/temperature, obtain the current state of the liquid cooling computing device.

In some embodiments, the liquid cooling computing devices may be in different states depending on their internal load and operating conditions, including but not limited to idle state, low power consumption state and working state. The idle state can be understood as when the liquid cooling computing device is not processing any computing tasks or the load is extremely low, most of its hardware is in standby mode, consuming less power and generating relatively less heat. The low power consumption state can be understood as the liquid cooling computing device is running, but the processing load is not high such that the overall power consumption is relatively low. The working state can be understood as when liquid cooling computing device processes high-load tasks, the power consumption of its internal hardware (such as CPU, GPU, etc.) increases significantly, and the heat generated increases significantly.

A2, if the current state of the liquid cooling computing device is an idle state or a low power consumption state, control the cooling unit to reduce the flow rate of the coolant and/or adjust the temperature of the coolant.

In some embodiments, when the liquid cooling computing device is in the idle state, the liquid cooling computing device can control the cooling unit through the BMC of the first monitored object to reduce the flow rate of the coolant to the minimum flow rate of the coolant, and/or appropriately adjust the temperature of the coolant to maintain a low temperature environment inside the liquid cooling computing device. In this way, the device can be kept ready to start working at any time, and energy can be effectively saved. At the same time, by monitoring and controlling the cooling unit through BMC, the cooling efficiency and energy consumption balance of liquid cooling computing device in idle state can be achieved, thereby improving the overall performance and service life of the device.

In some embodiments, when the liquid cooling computing device is in the low power consumption state, the liquid cooling computing device can control the cooling unit to reduce the flow of coolant in a timely manner and/or adjust the temperature of coolant appropriately to maintain the optimal operating temperature of the device to ensures that energy is not wasted due to overcooling based on the actual heat generated by the liquid cooling computing device through the BMC of the first monitored object. In this way, by monitoring and controlling the cooling unit through the BMC, the cooling efficiency and energy consumption balance of liquid cooling computing device can be achieved in the low power consumption state, thereby improving the overall performance and service life of the device.

In some embodiments, the process at 404, based on the first determination result, controlling the cooling unit to adjust the flow rate of the coolant and/or the temperature of the coolant, can be realized through one or more of the following steps.

B1, if the first determination result indicates that there is a monitored object with abnormal temperature, the largest first operating parameter may be selected from a plurality of first operating parameters corresponding to the monitored object with abnormal temperature; based on the maximum first operating parameter, the cooling unit may be controlled to gradually increase the flow rate of the coolant and/or gradually reduce the temperature of the coolant.

In some embodiments, gradually adjusting the flow rate of the coolant may be to increase or decrease the flow rate of the coolant output by the current cooling unit with a first preset weight. The first preset weight can be pre-set based on multiple factors such as temperature difference, server load, cooling demand, etc., to guide the cooling unit to change the coolant flow rate proportionally. The first preset weight can be any value between 0.1 and 0.2. Of course, the first preset weight can be other values, which is not limited in the embodiments of the present disclosure. In some embodiments, gradually adjusting the flow rate of the coolant may also be to increase or decrease the flow rate of the coolant output by the current cooling unit at a fixed flow rate.

Consistent with the present disclosure, when a monitored object with abnormal temperature is determined through the BMC of the first monitored object, the first operating parameter characterizing the highest temperature can be selected from the plurality of first operating parameters corresponding to the monitored object with abnormal temperature. The first operating parameter with the highest temperature can represent the biggest heat dissipation challenge currently faced, which means that the temperature of the monitored object is the highest and needs to be cooled down urgently. Based on the first operating parameter representing the highest temperature, a targeted cooling strategy can be adopted by controlling the cooling unit through the BMC of the first monitored object. That is, by gradually increasing the circulation rate of the coolant in the area where the abnormal monitored object is located, the cooling efficiency can be improved, the excess heat can be quickly removed from the equipment, and the temperature can be reduced. Alternatively, the coolant temperature can be gradually reduced. If the temperature of the coolant itself is too high to effectively absorb the heat generated by the device, the temperature of the coolant can be gradually reduced to increase the heat absorption capacity, thereby achieving a better cooling effect. In this way, cooling adjustments can be made quickly for monitored objects with abnormal temperatures, thereby shortening the response time for the temperature to return to normal. At the same time, based on the actual temperature conditions, by gradually adjusting the coolant flow rate as needed, the internal temperature of each monitored object can be controlled more accurately to prevent overheating or overcooling, thereby ensuring that the server runs stably within the ideal temperature range, and extending the hardware service life. In addition, unnecessary waste of coolant flow can be avoided as the cooling power is increased only when it is really needed, thereby saving energy and reducing the operating cost of the cooling system. Timely and effective cooling can protect the device from high temperature damage and helps to extend the service life and stability of the device. Finally, through a reasonable and effective cooling strategy, the performance of the entire liquid cooling computing device can be optimized, thereby improving the overall work efficiency and reliability of the system.

B2, if the first determination result indicates that there is a target liquid cooling sub-pipeline with abnormal flow rate, determining the minimum flow rate from the flow rates corresponding to the target liquid cooling sub-pipeline with abnormal flow; gradually increasing the flow rate of the coolant based on the minimum flow rate.

In some embodiments, when the BMC of the first monitored object determines that there is a target liquid cooling sub-pipeline with abnormal flow rate, the minimum flow rate can be determined from the flow rates corresponding to the target liquid cooling sub-pipeline with abnormal flow rate. Based on the determined minimum flow rate, the BMC of the first monitored object can control the cooling unit to gradually increase the output coolant flow rate, thereby increasing the coolant flow rate of the target liquid cooling sub-pipeline, ensuring that the coolant can fully contact and take away the heat in the target liquid cooling sub-pipeline, thereby improving the cooling efficiency. In this way, the operation of gradually increasing the coolant flow rate based on the minimum flow rate of the target liquid cooling sub-pipe with abnormal flow rate can not only address the local heat dissipation concern, but also facilitate the performance optimization and stable operation of the entire liquid cooling computing device.

B3, if the first determination result indicates that there is a target liquid cooling sub-pipe with abnormal temperature, determining the maximum temperature from the temperatures corresponding to the target liquid cooling sub-pipe with abnormal temperature; controlling the cooling unit to gradually reduce the temperature of the coolant based on the maximum temperature.

In some embodiments, when the BMC of the first monitored object determines that there is a target liquid cooling sub-pipe with abnormal temperature, that is, during the monitoring process, it is found that the temperature of a liquid cooling sub-pipe exceeds the preset threshold or is significantly higher than that of other sub-pipes, the maximum temperature is determined from the data of these temperature anomalies. Based on the maximum temperature, the cooling unit can be controlled by the BMC of the first monitored object to gradually reduce the temperature of the coolant to enhance the ability of the coolant to absorb the heat of the target liquid cooling sub-pipeline. In this way, by gradually lowering the temperature of the coolant based on the maximum temperature of the target liquid cooling sub-pipeline with abnormal temperature, the heat dissipation process can be controlled more accurately to prevent other unnecessary fluctuations caused by overcooling. At the same time, local overheating in a targeted manner can be addressed, and a good heat dissipation state of the entire liquid cooling computing device can be maintained, thereby ensuring long-term stable and efficient operation of the device, and achieving the purpose of energy saving.

In some embodiments, when the first confirmation result indicates one or more of the monitored object with abnormal temperature, the target liquid cooling sub-pipe with abnormal flow rate, and the target liquid cooling sub-pipe with abnormal temperature, after the flow rate and/or temperature of the coolant output from the cooling unit is adjusted through the BMC of the first monitored object, the following step may be performed:

If the flow rate of the cooling unit after adjustment does not meet a first flow rate condition, and/or the temperature after adjustment does not meet a first temperature condition, determining that the cooling unit is in an un-adjustable state, and outputting the first information. The first information may include at least one of a monitored object with abnormal temperature, a target liquid cooling sub-pipeline with abnormal flow rate, and a target liquid cooling sub-pipeline with abnormal temperature.

In some embodiments, the first flow rate condition may be that the flow rate of the coolant output by the cooling unit is within a second preset flow rate range. The second preset flow rate range may be determined based on the server chassis M included in the liquid cooling computing device and the number of servers N included in each server chassis. Assume that the flow rate required by a single server is 2L/M, the second preset flow rate range may be set to [2*N*M−20, 2*N*M+30]. Of course, the second preset flow rate range can also be set based on experience, which is not limited in the embodiments of the present disclosure.

In some embodiments, the first temperature condition may be that the temperature of the coolant output by the cooling unit is within a first preset temperature range. For example, the first preset temperature range may be [20, 50]. Of course, the first preset temperature range can also be set based on experience, which is not limited in the embodiments of the present disclosure.

Consistent with the present disclosure, after the flow rate and/or temperature of the coolant outputted from the cooling unit is adjusted by the BMC of the first monitored object, the adjusted flow rate cannot meet the preset first flow rate condition, and/or the adjusted temperature cannot meet the preset first temperature condition, and the BMC of the first monitored object can determine that the cooling unit is in a state that cannot be effectively adjusted. In this case, the BMC of the first monitored object can output the first information. The first information may include at least one or more of a monitored object with abnormal temperature, a target liquid cooling sub-pipeline with an abnormal flow rate, and a target liquid cooling sub-pipeline with abnormal temperature.

In some embodiments, the first information may include the monitored object with abnormal temperature. The first information may indicate the specific device or component whose current temperature exceeds the safe range or set threshold, thereby providing direction for the next step of troubleshooting or cooling strategy optimization.

In some embodiments, the first information may include the target liquid cooling sub-pipeline with abnormal flow. The first information may indicate the location of the liquid cooling sub-pipeline where the coolant flow does not meet the preset requirements. The liquid cooling sub-pipeline may be blocked, leaking, or have insufficient pumping capacity to provide clues for repairing or improving the cooling system layout.

In some embodiments, the first information may include the target liquid cooling sub-pipeline with abnormal temperature. The first information may indicate a liquid-cooled sub-pipeline whose temperature is too high and cannot be reduced to a suitable level by adjusting the current cooling unit, which helps engineers locate and solve the root cause of overheating.

The output of the first information is intended to quickly notify data center managers or automated operation and maintenance systems that the current cooling unit can no longer effectively regulate specific temperature or flow anomalies through conventional means, and more in-depth investigation and maintenance measures are needed to ensure the safe and stable operation of liquid cooling computing device.

Embodiments of the present disclosure provide a liquid cooling control method. The method can be applied to liquid cooling computing devices. FIG. 7 is a flowchart of the liquid cooling control method according to some embodiments of the present disclosure. The method will be described in detail below.

701, receiving the second information sent by the cooling unit at a second time through the BMC of the first monitored object.

The second information may include a second operating parameter, a third operating parameter, and a fourth operating parameter. The second operating parameter may indicate the pressure change of the cooling unit, the third operating parameter may indicate whether the cooling unit is faulty, and the fourth operating parameter may indicate the temperature of the coolant output by the cooling unit. The second time may be before the first time.

In some embodiments, the second operating parameter may be used to indicate the pressure change of the cooling unit at the second time. Pressure changes may reflect the working state of the cooling unit, such as whether the coolant is circulating smoothly, whether there is a blockage or leakage, etc. Over-pressure or under-pressure may affect the cooling effect and may even indicate a potential risk of failure.

In some embodiments, the third operating parameter may be used to confirm whether the cooling unit is faulty. If the third operating parameter indicates that there is indeed an issue with the cooling unit, it means that the cooling unit may not be working properly and needs to be checked and repaired in time to ensure the normal operation of the cooling unit and the stability and safety of the entire liquid cooling computing device.

In some embodiments, the fourth operating parameter may be used to provide coolant temperature data output by the cooling unit. The temperature of the coolant directly affects its cooling effect. Coolant temperature being too high may indicate reduced cooling efficiency, while coolant temperature being too low may reflect over-cooling or an issue with the cooling source.

Consistent with the present disclosure, in the process of monitoring and managing the liquid cooling computing device, the BMC of the first monitored object (such as a server or a server chassis) can receive the second information carrying the second operating parameter, the third operating parameter and the fourth operating parameter sent by the cooling unit at the second time. It should be noted that the second time may occur before the first time. Through the BMC of the first monitored object, the historical operation data of the cooling unit can be traced and analyzed. This time-sequential design helps technicians to more accurately evaluate and predict performance trends of cooling units before using them to cool servers or server chassis, identify and resolve problems in advance, and thus improve data center operation and maintenance efficiency and equipment lifespan.

702, determining whether the second determination result indicates there is an abnormality in the cooling unit based on one or more of the second operating parameter, the third operating parameter, and the fourth operating parameter.

In some embodiments, the second determination result may be one or more of: the pressure change of the cooling unit is normal; the pressure change of the cooling unit is abnormal; the cooling unit is not faulty; the cooling unit is faulty; the temperature of the coolant output by the cooling unit is normal; and the temperature of the coolant output by the cooling unit is abnormal.

Consistent with the present disclosure, after receiving the second information carrying the second operating parameter, the third operating parameter and the fourth operating parameter sent from the cooling unit at the second time through the BMC of the first monitored object, the operating state of the cooling unit can be fully evaluated to determine if there are any abnormalities based on one or more of the second operating parameter (pressure change of the cooling unit), the third operating parameter (whether the cooling unit fails), and the fourth operating parameter (temperature of the coolant output by the cooling unit). More specifically, based on the second operating parameter, if it is determined that the pressure change of the cooling unit exceeds the normal operating range, such as a sudden increase in pressure, it may indicate that the coolant circulation is blocked, the pump fails, or there is a blockage inside the cooling unit. Conversely, if the pressure is too low, it could indicate a coolant leak, an underpowered pump, or some other problem within the cooling system. Both of these conditions could indicate a possible malfunction in the cooling unit. Based on the third operating parameter, if the third operating parameter directly indicates that a failure has occurred in the cooling unit, it can be concluded that an abnormality has occurred in the cooling unit without much interpretation. Such fault signals may be provided by the cooling unit's built-in self-diagnostic functions, such as motor failure, sensor failure, control circuit error, etc. Based on the fourth operating parameter, if the fourth operating parameter indicates that the temperature of the coolant output by the cooling unit exceeds the normal temperature range, it may be caused by reduced cooling efficiency, poor coolant circulation, or cooling source failure. This situation also indicates that there may be an abnormality in the cooling unit.

In this way, by comprehensive analyzing of these three parameters, the health state of the cooling unit can be determined more accurately to promptly discover and deal with potential faults, and ensure the stable operation and cooling efficiency of liquid cooling computing device. After confirming that there is an abnormality in the cooling unit, the operation and maintenance personnel can take corresponding countermeasures, such as adjusting the cooling strategy, replacing faulty components, or performing maintenance and repairs on the entire cooling system.

703, based on the second determination result, controlling the cooling unit to adjust the flow rate of the coolant through the BMC of the first monitored object.

In some embodiments, after determining whether the cooling unit has an abnormal second determination result based on one or more of the second operating parameter, the third operating parameter, fourth operating parameter, the cooling unit can be controlled to adjust the flow rate of the coolant based on the second determination result through the BMC of the first monitored object.

In some embodiments, controlling the cooling unit to adjust the flow rate of the coolant through the BMC of the first monitored object based on the second determination result can be realized using the following methods.

In the first method, when the second determination result indicates that there is a pressure abnormality in the cooling unit, the cooling unit may be controlled to gradually increase or decrease the flow rate of the coolant through the BMC of the first monitored object until the cooling unit returns to normal.

In some embodiments, if the second determination result indicates that there is an abnormal pressure in the cooling unit, it may indicate that the pressure of the cooling unit is not within the normal working range, which may be caused by improper coolant flow or blockage in the cooling unit. In order to restore the normal working state of the cooling unit, the cooling unit may be intelligently adjusted through the BMC of the first monitored object. In the first case, if it is determined that the pressure abnormality is caused by insufficient coolant flow, the cooling unit can be controlled by the BMC of the first monitored object to gradually increase the coolant flow to improve the cooling effect by increasing the coolant circulation rate, reduce the system pressure, and return it to normal levels. In the second case, if the pressure abnormality is determined to be caused by excessive coolant flow causing excessive pressure, the BMC of the first monitored object can also be used to control the cooling unit to gradually reduce the coolant flow to reduce the internal pressure of the system and prevent the cooling system from being damaged due to excessive pressure. In this way, the BMC will continuously monitor the pressure changes of the cooling unit, provide real-time feedback based on the effect of each flow adjustment, and continuously optimize the adjustment strategy until the pressure of the cooling unit returns to normal, ensuring that the liquid-cooled computing equipment can operate stably and efficiently; at the same time, achieving dynamic adjustment and autonomous optimization.

In the second method, when the second determination result indicates that the cooling unit has a temperature abnormality, the cooling unit may be controlled to gradually increase or decrease the temperature of the coolant through the BMC of the first monitored object until the cooling unit returns to normal.

In some embodiments, if the second determination result indicates that the cooling unit has a temperature abnormality, that is, the temperature of the coolant output by the cooling unit is too high or too low and is not within the normal temperature range, to restore the normal working state of the cooling unit, the cooling unit may be intelligently temperature controlled through the BMC of the first monitored object. In the first case, the temperature of the coolant is too high, it may indicate that the cooling effect is poor or the cooling system's heat dissipation capacity is reduced. Through the BMC of the first monitored object, the cooling unit can be controlled to gradually reduce the temperature of the coolant, such as increasing the cooling power of the cooling equipment, optimizing the coolant circulation path, etc., until the coolant temperature returns to the preset ideal range, ensuring that the cooling unit returns to normal working state. In the second case, if the coolant temperature is too low, it may affect the cooling efficiency or cause condensation inside the cooling system. At this time, the temperature of the coolant can be gradually increased through the BMC of the first monitored object, such as adjusting the working mode of the heat exchanger or controlling the working intensity of the heating element, such that the coolant temperature returns to an appropriate level. In this way, the BMC can continuously monitor the temperature changes of the coolant output by the cooling unit, and dynamically adjusts the cooling strategy based on the feedback of the effect after each adjustment until the coolant output by the cooling unit returns to the normal working temperature, thereby ensuring the stable and efficient operation of the liquid cooling computing device.

In the third method, when the second determination result indicates that the temperature of the cooling unit is abnormal, a third message may be broadcast to all monitored objects, the third message being used to instruct all monitored objects to perform power capping or enter a low power consumption state; and output the third message, and the third message being used to indicate that the cooling unit is abnormal.

In some embodiments, power capping can be understood as setting the power limit of each server within a certain threshold to reduce overall energy consumption and heat load. The low power consumption state can be understood as the liquid cooling computing device is running, but the processing load is not high such that the overall power consumption is low. The working state can be understood as when the liquid cooling computing device is processing high-load tasks, the power consumption of its internal hardware (such as CPU, GPU, etc.) increases significantly, and the heat generated increases significantly. The low power consumption state may also be referred to as the power saving state.

In some embodiments, if the second determination result indicates that the cooling unit is faulty, a third message may be broadcast to all monitored objects through the BMC of the first monitored object. The content of this third message may be to instruct all monitored objects to perform power capping or enter a low power consumption state. In this way, through global collaborative control, even if there is a failure in the cooling unit, the stable operation of the liquid cooling computing device can be maintained as much as possible, while avoiding equipment overheating and performance degradation that may be caused by cooling problems, thereby extending the service life of the equipment and ensuring the energy efficiency of the data center. Of course, the third message can also clearly indicate that there is an abnormal condition in the current cooling unit such that the operation and maintenance personnel can obtain fault information in time, conduct further troubleshooting and repair work, and ensure the overall stable operation of the liquid cooling computing device. Through such a linkage mechanism, the equipment operation state can be quickly adjusted when a problem occurs in the cooling unit, thereby minimizing the impact on the normal operation of the system.

In some embodiments, the liquid cooling control method may include: if at least one of the following conditions is met: the adjusted flow rate meets a second flow rate condition, the lowered temperature meets a second temperature condition, and the second determination result indicates that the cooling unit is faulty, a third message may be broadcast to all monitored objects, the third message may be used to instruct all monitored objects to perform power capping or enter a low power consumption state; outputting the third message, the third message being used to indicate that the cooling unit is abnormal.

In some embodiments, the second flow condition may be that the flow rate of the coolant output by the cooling unit is within a third preset flow rate range. The third preset flow rate range may be the flow rate of the cooling liquid output by the cooling unit to meet the pressure requirement when cooling the server in the liquid cooling computing device. Of course, the third preset flow size range may also be set based on experience, which is not limited in the embodiments of the present disclosure.

In some embodiments, the second temperature condition may be that the temperature of the coolant output by the cooling unit is within the second preset temperature range. The first preset temperature range and the second preset temperature range may be the same or different. For example, the second preset temperature range may be [20, 50]. Of course, the second preset temperature range may also be set based on experience, which is not limited in the embodiments of the present disclosure.

Consistent with the present disclosure, when the second determination result indicates that there is a pressure anomaly and/or a temperature anomaly in the cooling unit, if, after adjusting the flow rate and/or temperature of the coolant output from the cooling unit through the BMC of the first monitored object, the adjusted flow rate cannot meet the preset second flow condition, and/or the adjusted temperature cannot meet the preset second temperature condition, at this time, the BMC of the first monitored object determines that the cooling unit is faulty, or, if the second determination result indicates that the cooling unit is faulty, the BMC of the first monitored object broadcasts a third message to all monitored objects. The content of this third message is to instruct all monitored objects to perform power capping or enter a low power consumption state. In this way, through global coordinated control, even in the case of abnormal cooling unit, the stable operation of liquid cooling computing devices can be maintained as much as possible. At the same time, it avoids equipment overheating and performance degradation that may be caused by cooling problems, prolongs the service life of the equipment, and ensures the energy efficiency of the data center. Of course, the third message will also clearly indicate that there is an abnormal condition in the current cooling unit such that the operation and maintenance personnel can obtain fault information in time, conduct further troubleshooting and repair work, and ensure the overall stable operation of the liquid cooling computing device. Through such a linked mechanism, the equipment operation states can be quickly adjusted when a problem occurs in the cooling unit to minimize the impact on the normal operation of the system.

704, using the BMC of the first monitored object in a liquid cooling computing device to obtain a plurality of first operating parameters of each monitor object at a first time.

In some embodiments, the first operating parameter may characterize the temperature of the monitored objects. The monitored objects may include at least one server chassis in the liquid cooling computing device, and at least one server located on each server chassis, and the first monitored object may be one of the monitored objects.

705, using the BMC of the first monitored object to control the cooling unit in the liquid cooling computing device to adjust the flow rate and/or temperature of the coolant based on the first operating parameter.

In the liquid cooling control methods provided in the embodiments of the present application, the liquid cooling computing device may be a server rack. The server rack may be provided with at least one server chassis, a network switch and a CDU (corresponding to the cooling unit described above). Each server chassis may include at least one server. As shown in FIG. 8, the process of adjusting the CDU based on the state of the server chassis and the server node can be realized by the following steps.

801, perform BMC election through all BMCs to determine a target BMC.

The target BMC may correspond to the BMC of the first monitored object described above, and the target BMC may be the selected BMC among all BMCs.

In some embodiments, the BMC may be the baseboard management controller corresponding to each server chassis and each server node.

802, scan the thermal state of each server node through the target BMC.

In some embodiments, the thermal state of the server node may correspond to the first operating parameter described above.

803, determine whether each server node is normal based on the thermal state of each server node through the target BMC.

If the target BMC determines that each server node is normal based on the thermal state of each server node, perform the process at 804. If the target BMC determines that each server node is normal based on the thermal state of each server node, perform the process at 806.

804, determine whether the current state of the server rack is an idle state or a low power consumption state through the target BMC.

If the current state of the server rack is idle or low power consumption, perform the process at 805. If the current state of the server rack is not an idle state or a low power consumption state, the process returns to 802, and the target BMC continues to scan the thermal state of each server node, thereby achieving continuous monitoring of each server node.

805, the target BMC controls the CDU to adjust the flow rate of the output coolant to a minimum flow rate, and/or adjust the temperature of the output coolant to a third preset temperature.

In some embodiments, the third preset temperature may be the temperature at which the coolant output by the CDU produces the lowest power consumption when the current state of the server rack is idle or low power consumption.

In some embodiments, event reminder information may also be sent through the target BMC to remind the user that the CDU is set to the minimum flow rate and the temperature with the lowest power consumption.

806, the target BMC controls the CDU to increase or decrease the flow rate of the output coolant to the flow rate, and/or to reduce the temperature of the output coolant.

In some embodiments, increasing or decreasing the flow rate of the coolant output by the CDU may be to increase or decrease the flow rate of the coolant output by the current cooling unit by a first preset weight, such as 10%.

807, the target BMC determines whether the thermal state of each server node is normal.

In some embodiments, if the target BMC determines that the thermal state of each server node is normal again, the process returns to 802, and the target BMC continues to scan the thermal state of each server node, thereby achieving continuous monitoring of each server node and server, and continuous adjustment of the CDU. If it is determined again through the target BMC that the thermal state of each server node is abnormal, the process returns to 808.

808, the target BMC determines whether the flow rate/temperature adjusted by the CDU exceeds the maximum flow rate/temperature and the minimum flow rate/temperature.

In some embodiments, when adjusting the flow rate and temperature of the coolant in the CDU, the adjusted flow rate of the coolant in the CDU needs to be between the maximum flow rate and the minimum flow rate, and the adjusted temperature of the coolant in the CDU needs to be between the maximum temperature and the minimum temperature. If the adjusted flow/temperature exceeds the maximum flow/temperature and the minimum flow/temperature, it may indicate that the CDU cannot be adjusted, that is, the CDU setting is blocked, and the process at 809 can be performed. If the adjusted flow rate/temperature does not exceed the maximum flow rate/temperature and the minimum flow rate/temperature, then the process returns to 806 and the target BMC continues to control the CDU to increase or decrease the flow rate of the output coolant to the flow rate, and/or reduce the temperature of the output coolant.

809, the target BMC sets the server node or server chassis with abnormal thermal state to the save mode.

In some embodiments, the target BMC may also send an error event prompt message to prompt the user that an abnormal server node or server chassis exists.

Consistent with the present disclosure, through the interaction and negotiation of all BMCs, a target BMC can be determined as the master control node, which is responsible for the overall management of the monitoring and control of the entire liquid cooling system. The target BMC scans the real-time thermal state of each server node in turn, collecting relevant parameters including temperature, current, voltage, etc. Based on the collected thermal state data, the target BMC analyzes the working status of each server node to determine whether it is within the normal operating range. The target BMC further determines whether the server rack is currently in an idle state or a low power consumption state to make appropriate cooling strategy adjustments. Subsequently, the target BMC controls the CDU to adjust the flow and temperature of the output coolant according to the current room load and server node state. During low load or idle periods, coolant flow is reduced to a minimum flow rate or the temperature is adjusted to a preset third preset temperature to save energy. Further, as the load changes, the target BMC can increase or decrease the flow rate of the coolant, or continue to reduce the temperature of the output coolant based on the real-time thermal status of the server node to keep the server node in the normal operating temperature range. After the cooling strategy is adjusted, the target BMC will detect the thermal state of each server node again to confirm whether it has returned to normal. That is, the target BMC will also check whether the coolant flow rate and temperature adjusted by the CDU exceed the safety boundaries of the maximum flow rate/temperature and minimum flow rate/temperature specified by the system. Finally, for server nodes or servers that are still in abnormal thermal state, the target BMC will take measures, such as setting them to safe mode, stopping non-critical tasks, reducing overall power consumption, and preventing hardware damage due to overheating.

Refer to FIG. 9, the process of adjusting the CDU based on the CDU state may be realized through the following steps.

901, perform BMC election through all BMCs to determine a target BMC.

The target BMC may correspond to the BMC of the first monitored object described above, and the target BMC may be the selected BMC among all BMCs.

In some embodiments, the BMC may be the baseboard management controller corresponding to each server chassis and each server node.

902, the target BMC scans the CDU state.

In some embodiments, the state of the CDU may correspond to the second operating parameter, the third operating parameter and the fourth operating parameter described above, and the state of the CDU may include but is not limited to changes in pressure, flow rate and temperature of the coolant.

If the target BMC determines that the CDU is normal based on the CDU status, then the process returns to 902 and the target BMC continue to scan and monitor the CDU state;

if the target BMC determines that the CDU is abnormal based on the CDU state, then the process at 904 can be performed.

904, the target BMC controls the CDU to increase or decrease the output coolant flow rate and/or increase or decrease the output coolant temperature.

905, the target BMC determines whether the CDU state is normal again.

If the target BMC determines that the state of the CDU is normal again, the process returns to 902 and the target BMC continues to scan and monitor the state of the CDU, thereby achieving continuous monitoring and adjustment of the CDU. If the target BMC determines that the CDU is abnormal again, the process at 906 can be performed.

906, the target BMC broadcasts to all server chassis and server nodes corresponding to the BMC to enter power saving mode.

In some embodiments, the target BMC may also send error event prompt information to remind the user that there is an abnormality in the CDU.

Consistent with the present disclosure, through the interaction and negotiation of all BMCs, a target BMC can be determined as the master control node, which is responsible for the overall management of the monitoring and control of the CDU of the entire liquid cooling system. The target BMC first scans the state of the CDU, including but not limited to key operating parameters such as coolant flow, temperature, pressure, power status, etc., to determine whether the CDU is in normal working condition. If there is an abnormality in the CDU, the target BMC will accurately adjust the output coolant flow rate and increase or decrease the coolant temperature based on the actual status of the CDU to restore it to the normal working range as soon as possible. After adjusting the coolant flow rate and temperature, the target BMC will check the status of the CDU again to verify whether the adjustment measures are effective to ensure that the CDU can provide cooling services normally. If the CDU does not return to normal, the target BMC will broadcast a command to all BMCs, instructing the corresponding server chassis and server nodes to enter power saving mode, which can reduce system power consumption and heat generation, thereby potentially reducing cooling requirements, saving energy, and extending equipment life. In this way, through centralized management and intelligent regulation, not only can the liquid cooling system be precisely controlled to ensure its stable operation, but energy-saving optimization can also be performed according to actual conditions, thereby improving the overall energy efficiency and operation and maintenance efficiency of the data center.

Embodiments of the present disclosure provide a liquid cooling control device.

The liquid cooling control device can be used to implement the liquid cooling control method provided in the embodiments corresponding to FIG. 2, FIG. 4 and FIG. 7. As shown in FIG. 10, the liquid cooling control device 10 includes an acquisition module 1001 and a control module 1002.

In some embodiments, the acquisition module 1001 may be configured to obtain a plurality of first operating parameters of each monitored object at a first time by using a BMC of a first monitored object in a liquid cooling computing device.

In some embodiments, the first operating parameter may characterize the temperature of the monitored objects. The monitored objects may include at least one server chassis in the liquid cooling computing device, and at least one server located on each server chassis, and the first monitored object may be one of the monitored objects.

In some embodiments, the control module 1002 may be configured to control the cooling unit in the liquid cooling computing device through the BMC of the first monitored object and adjust the flow rate and/or temperature of the coolant based on the first operating parameters of each monitored object.

Embodiments of the present disclosure provide a liquid cooling computing device. The liquid cooling computing device can be used to implement the liquid cooling control method provided in the embodiments corresponding to FIG. 2, FIG. 4 and FIG. 7. As shown in FIG. 11, the liquid cooling computing device 100 (the liquid cooling computing device 100 in FIG. 11 corresponds to the liquid cooling control device 10 in FIG. 10) includes a processor 1101, a memory 1102, and a communication bus 1103.

In some embodiments, the communication bus 1103 may be used to realize the communication connection between the processor 1101 and the memory 1102.

In some embodiments, the processor 1101 may be configured to execute the liquid cooling control program stored in the memory 1102 to use the BMC of a first monitored object in a liquid cooling computing device to obtain a plurality of first operating parameters of each monitoring object at a first time, and, based on the first operating parameters of each monitored object, use the BMC of the first monitored object to control the cooling unit in the liquid cooling computing device to adjust the flow rate and/or temperature of the coolant.

In some embodiments, the first operating parameter may characterize the temperature of the monitored objects. The monitored objects may include at least one server chassis in the liquid cooling computing device, and at least one server located on each server chassis, and the first monitored object may be one of the monitored objects.

In some embodiments, the processor 1101 may be configured to execute the liquid cooling control program stored in the memory 1102 to respond to a first instruction and determine a first monitored object based on the first instruction; obtain a plurality of first operating parameter of the first monitored object at a first time through the BMC of the first monitored object; receive, through the BMC of the first monitored object, the plurality of first operating parameter obtained at the first time and sent by the BMC of at least one second monitored object.

In some embodiments, the processor 1101 may be configured to execute the liquid cooling control program stored in the memory 1102 to use the flow rate/temperature sensor to obtain the coolant monitoring information of each target liquid cooling sub-pipeline at the first time, the target liquid cooling sub-pipeline being the liquid cooling sub-pipeline corresponding to each server chassis in the liquid cooling computing device, the coolant monitoring information including the flow rate and/or temperature of the coolant. The processor 1101 may be further configured to, based on the first operating parameter and/or the coolant monitoring information, determine whether there is a monitored object with abnormal temperature, and/or whether there is a first determination result of a target liquid cooling sub-pipeline with abnormal flow rate/temperature; and, based on the first determination result, control the cooling unit to adjust the flow rate of the coolant and/or the temperature of the coolant.

In some embodiments, the processor 1101 may be configured to execute the liquid cooling control program stored in the memory 1102 to, if the first determination result indicates that there is no monitored object with abnormal temperature, and/or there is no target liquid cooling sub-pipeline with abnormal flow rate/temperature, obtain the current state of the liquid cooling computing device; if the current state of the liquid cooling computing device is an idle state or a low power consumption state, control the cooling unit to reduce the flow rate of the coolant and/or adjust the temperature of the coolant.

In some embodiments, the processor 1101 may be configured to execute the liquid cooling control program stored in the memory 1102 to, if the first determination result indicates that there is a monitored object with abnormal temperature, select the largest first operating parameter from a plurality of first operating parameters corresponding to the monitored object with abnormal temperature; based on the maximum first operating parameter, control the cooling unit to gradually increase the flow rate of the coolant and/or gradually reduce the temperature of the coolant; and/or, if the first determination result indicates that there is a target liquid cooling sub-pipeline with abnormal flow rate, determine the minimum flow rate from the flow rates corresponding to the target liquid cooling sub-pipeline with abnormal flow; gradually increase the flow rate of the coolant based on the minimum flow rate; and/or, if the first determination result indicates that there is a target liquid cooling sub-pipe with abnormal temperature, determine the maximum temperature from the temperatures corresponding to the target liquid cooling sub-pipe with abnormal temperature; control the cooling unit to gradually reduce the temperature of the coolant based on the maximum temperature.

In some embodiments, the processor 1101 may be configured to execute the liquid cooling control program stored in the memory 1102 to, if the flow rate of the cooling unit after adjustment does not meet a first flow rate condition, and/or the temperature after adjustment does not meet a first temperature condition, determine that the cooling unit is in an un-adjustable state, and output the first information. The first information may include at least one of a monitored object with abnormal temperature, a target liquid cooling sub-pipeline with abnormal flow rate, and a target liquid cooling sub-pipeline with abnormal temperature.

In some embodiments, the processor 1101 may be configured to execute the liquid cooling control program stored in the memory 1102 to receive the second information sent by the cooling unit at a second time through the BMC of the first monitored object. The second information may include a second operating parameter, a third operating parameter, and a fourth operating parameter. The second operating parameter may indicate the pressure change of the cooling unit, the third operating parameter may indicate whether the cooling unit is faulty, and the fourth operating parameter may indicate the temperature of the coolant output by the cooling unit. The second time may be before the first time. The processor 1101 may be further configured to determine whether the second determination result indicates that there is an abnormality in the cooling unit based on one or more of the second operating parameter, the third operating parameter, and the fourth operating parameter. In addition, the processor 1101 may be configured to, based on the second determination result, control the cooling unit to adjust the flow rate of the coolant through the BMC of the first monitored object.

In some embodiments, the processor 1101 may be configured to execute the liquid cooling control program stored in the memory 1102 to, when the second determination result indicates that there is a pressure abnormality in the cooling unit, control the cooling unit to gradually increase or decrease the flow rate of the coolant through the BMC of the first monitored object until the cooling unit returns to normal; when the second determination result indicates that the cooling unit has a temperature abnormality, control the cooling unit to gradually increase or decrease the temperature of the coolant through the BMC of the first monitored object until the cooling unit returns to normal.

In some embodiments, the processor 1101 may be configured to execute the liquid cooling control program stored in the memory 1102 to, if at least one of following condition is met: the adjusted flow rate does not meet the second flow rate condition, the lowered temperature does not meet the second temperature condition, and the second determination result indicates that the cooling unit fails, broadcast a third message to all monitored objects. The third message may be used to instruct all monitored objects to perform power capping or enter a low power consumption state. In addition, the processor 1101 may be further configured to output the third massage, the third message being used to indicate that the cooling unit is abnormal.

The method provided in the embodiments of the present disclosure can be directed embodied as a software module combination executed by the processor 1101. The software module may be located in a storage medium. The storage medium may be located in the memory 1102. The processor 1101 reads the executable instructions included in the software module in the memory 1102 and completes the method provided in the embodiments of the present disclosure in combination with the necessary hardware.

As an example, the processor 1101 may be an integrated circuit chip having signal processing capabilities, such as a general-purpose processor, a digital signal processor (DSP), or other programmable logic devices, discrete gate or transistor logic devices, discrete hardware components, etc. A general-purpose processor may be a microprocessor or any conventional processor or the like.

It should be noted that for the specific implementation process of the steps executed by the processor in this embodiment, reference can be made to the implementation process of the information display method provided in the corresponding embodiments of FIG. 1 to FIG. 3, and will not be repeated here.

Embodiments of the present disclosure provide a storage medium storing a computer program. When the computer program is executed by at least one processor, the implementation process of the liquid cooling control method provided in the embodiments corresponding to FIG. 2, FIG. 4 and FIG. 7 can be implemented, and details will not be repeated here.

Embodiments of the present disclosure provide a computer program product, including a computer program or an instruction. When the computer program is executed by at least one processor, the implementation process of the liquid cooling control method provided in the embodiments corresponding to FIG. 2, FIG. 4 and FIG. 7 can be implemented, and details will not be repeated here.

Those skilled in the art should understand that the embodiments of the present disclosure may be provided as methods, systems, or computer program products. Accordingly, the present disclosure may take the form of a hardware embodiment, a software embodiment, or an embodiment combining software and hardware aspects. Further, the present disclosure may take the form of a computer program product embodied on one or more computer-readable storage media (including but not limited to a magnetic disk and an optical disk, etc.) having computer-readable program code embodied therein.

The present disclosure is described with reference to flowcharts and/or block diagrams of methods, devices (systems), and computer program products according to embodiments of the present disclosure. It should be understood that each procedure and/or block in the flowchart and/or block diagram, and a combination of procedures and/or blocks in the flowchart and/or block diagram can be realized by computer program instructions. The computer program instructions may be provided to a general-purpose computer, a special-purpose computer, an embedded processor, or a processor of other programmable data processing equipment to produce a machine such that the program instructions executed by the processor of the computer or other programmable data processing equipment produce an apparatus for realizing the functions specified in one or more processes of the flowchart and/or one or more blocks of the block diagram.

These computer program instructions may also be stored in a computer-readable memory capable of directing a computer or other programmable data processing apparatus to operate in a specific manner, such that the computer program instructions stored in the computer-readable memory produce an article of manufacture comprising instruction means, the instructions. The device realizes the function specified in one or more processes of the flowchart and/or one or more blocks of the block diagram.

The computer program instructions can also be loaded onto a computer or other programmable data processing device, causing a series of operational steps to be performed on the computer or other programmable device to produce a computer-implemented process, thereby implementing the functions specified in the flow chart or blocks of the flowchart and/or the block or blocks of the block diagrams.

The above description of the disclosed embodiments enables those skilled in the art to implement or use the present disclosure. Various modifications to the embodiments will be obvious to those skilled in the art, and the general principles defined herein can be implemented in other embodiments without departing from the spirit or scope of the present disclosure. Therefore, this application will not be limited to the embodiments shown in the specification, but should conform to the broadest scope consistent with the principles and novelties disclosed in the specification.

What is claimed is:

1. A liquid cooling control method comprising:
using a baseboard management controller (BMC) of a first monitored object in a liquid cooling computing device to obtain a plurality of first operating parameters of each monitored object at a first time; and
controlling a cooling unit in the liquid cooling computing device to adjust a flow rate and/or temperature of coolant through the BMC of the first monitored object based on the plurality of first operating parameters of each of the monitored objects, wherein:
the first operating parameter characterizes the temperature of the monitored object, and the monitored object includes at least one server chassis in the liquid cooling computing device and at least one server located on each server chassis, the first monitored object being one of all monitored objects.

2. The liquid cooling control method of claim 1, wherein using the BMC of the first monitored object in the liquid cooling computing device to obtain the plurality of first operating parameters of each monitored object at the first time includes:
responding to a first instruction and determining the first monitored object based on the first instruction;
obtaining the plurality of first operating parameters of the first monitored object at the first time through the BMC of the first monitored object; and
receiving the plurality of first operating parameters obtained at the first time and sent by a BMC of at least one second monitored object through the BMC of the first monitored object.

3. The liquid cooling control method of claim 1, wherein, controlling the cooling unit in the liquid cooling computing device to adjust the flow rate and/or temperature of coolant through the BMC of the first monitored object based on the plurality of first operating parameters of each of the monitored objects includes:
obtaining coolant monitoring information of each target liquid cooling sub-pipeline at the first time through a flow rate/temperature sensor, the target liquid cooling sub-pipeline being a liquid cooling sub-pipeline corresponding to each server chassis in the liquid cooling computing device, the coolant monitoring information including the flow rate and/or temperature of the coolant;
based on the first operating parameter and/or the coolant monitoring information, determining whether there is a monitored object with abnormal temperature, and/or whether there is a first determination result of the target liquid cooling sub-pipeline with abnormal flow rate/temperature; and
controlling the cooling unit to adjust the flow rate of the coolant and/or the temperature of the coolant based on the first determination result.

4. The liquid cooling control method of claim 3, wherein, controlling the cooling unit to adjust the flow rate of the coolant and/or the temperature of the coolant based on the first determination result includes:
obtaining a current state of the liquid cooling computing device if the first determination result indicates that there is no monitored object with abnormal temperature, and/or there is no target liquid cooling sub-pipeline with abnormal flow/temperature; and
controlling the cooling unit to reduce the flow rate of the coolant and/or adjusting the temperature of the coolant if the current state of the liquid cooling computing device is an idle state or a low power consumption state.

5. The liquid cooling control method of claim 3, wherein, controlling the cooling unit to adjust the flow rate of the coolant and/or the temperature of the coolant based on the first determination result includes:
selecting a maximum first operating parameter from the plurality of first operating parameters corresponding to the monitored object with abnormal temperature if the first determination result indicates that there is a monitored object with abnormal temperature; controlling the cooling unit to gradually increase the flow rate of the coolant and/or gradually reduce the temperature of the coolant based on the maximum first operating parameter; and/or,
determining a minimum flow rate from the flow rate corresponding to the target liquid cooling sub-pipeline with abnormal flow rate if the first determination result indicates that there is a target liquid cooling sub-pipeline with abnormal flow; controlling the cooling unit to gradually increase the flow rate of the coolant based on the minimum flow rate; and/or,
determining a maximum temperature from the temperature corresponding to the target liquid cooling sub-pipeline with abnormal temperature if the first determination result indicates that there is a target liquid cooling sub-pipeline with abnormal temperature; controlling the cooling unit to gradually reduce the temperature of the coolant based on the maximum temperature.

6. The liquid cooling control method of claim 5, further comprising:
determining that the cooling unit is in an un-adjustable state and outputting first information if the flow rate after adjustment of the cooling unit does not meet a first flow condition, and/or the temperature after adjustment does not meet a first temperature condition, the first information including at least one of the monitored object with abnormal temperature, the target liquid cooling sub-pipeline with abnormal flow rate, or the target liquid cooling sub-pipeline with abnormal temperature.

7. The liquid cooling control method of claim 1, wherein before controlling the cooling unit in the liquid cooling computing device to adjust a flow rate and/or temperature of coolant through the BMC of the first monitored object based on the plurality of first operating parameters of each of the monitored objects, the method further comprising:
receiving, through the BMC of the first monitored object, second information sent by the cooling unit at a second time, the second information including a second operating parameter, a third operating parameter and a fourth operating parameter, the second operating parameter being used to indicate a pressure change of the cooling unit, the third operating parameter being used to indicate whether the cooling unit fails, and the fourth operating parameter being used to indicate the temperature of the coolant output by the cooling unit; the second time being is before the first time;
determining a second determination result to determine whether there is an abnormality in the cooling unit based on one or more of the second operating parameter, the third operating parameter, and the fourth operating parameter; and
controlling the cooling unit to adjust the flow rate of the coolant through the BMC of the first monitored object based on the second determination result.

8. The liquid cooling control method of claim 7, wherein controlling the cooling unit to adjust the flow rate of the coolant through the BMC of the first monitored object based on the second determination result includes:
when the second determination result indicates that the cooling unit has abnormal pressure, controlling the cooling unit to gradually increase or decrease the flow rate of the coolant through the BMC of the first monitored object until the cooling unit returns to normal; and
when the second determination result indicates that the cooling unit has a temperature abnormality, controlling the cooling unit to gradually increase or decrease the temperature of the coolant through the BMC of the first monitored object until the cooling unit returns to normal.

9. The liquid cooling control method of claim 8 further comprising:
broadcasting a third message to all monitored objects if one or more of the following conditions is met: the adjusted flow rate does not satisfy a second flow rate condition, the lowered temperature does not satisfy a second temperature condition, and the second determination result indicates that the cooling unit fails, the third message being used to instruct all the monitored objects to perform power capping or enter the low power consumption state; and
outputting the third message, the third message being used to indicate that the cooling unit is abnormal.

10. A liquid cooling computing device comprising:
a processor;
a memory storing program instructions;
a communication bus, the communication bus being used to establish a communication connection between the processor and the memory, wherein:
the program instructions stored in the memory, when being executed by the processor, cause the processor to:
use a baseboard management controller (BMC) of a first monitored object in the liquid cooling computing device to obtain a plurality of first operating parameters of each monitored object at a first time; and
control a cooling unit in the liquid cooling computing device to adjust a flow rate and/or temperature of coolant through the BMC of the first monitored object based on the plurality of first operating parameters of each of the monitored objects, wherein:
the first operating parameter characterizes the temperature of the monitored object, and the monitored object includes at least one server chassis in the liquid cooling computing device and at least one server located on each server chassis, the first monitored object being one of all monitored objects.

11. The liquid cooling computing device of claim 10, wherein, when executed by the processor, the program instructions cause the processor to:
respond to a first instruction and determine the first monitored object based on the first instruction;
obtain the plurality of first operating parameters of the first monitored object at the first time through the BMC of the first monitored object; and
receive the plurality of first operating parameters obtained at the first time and sent by a BMC of at least one second monitored object through the BMC of the first monitored object.

12. The liquid cooling computing device of claim 10, wherein, when executed by the processor, the program instructions cause the processor to:
obtain coolant monitoring information of each target liquid cooling sub-pipeline at the first time through a flow rate/temperature sensor, the target liquid cooling sub-pipeline being a liquid cooling sub-pipeline corresponding to each server chassis in the liquid cooling computing device, the coolant monitoring information including the flow rate and/or temperature of the coolant;
based on the first operating parameter and/or the coolant monitoring information, determine whether there is a monitored object with abnormal temperature, and/or whether there is a first determination result of the target liquid cooling sub-pipeline with abnormal flow rate/temperature; and
control the cooling unit to adjust the flow rate of the coolant and/or the temperature of the coolant based on the first determination result.

13. The liquid cooling computing device of claim 12, wherein, when executed by the processor, the program instructions cause the processor to:
obtain a current state of the liquid cooling computing device if the first determination result indicates that there is no monitored object with abnormal temperature, and/or there is no target liquid cooling sub-pipeline with abnormal flow/temperature; and
control the cooling unit to reduce the flow rate of the coolant and/or adjust the temperature of the coolant if the current state of the liquid cooling computing device is an idle state or a low power consumption state.

14. The liquid cooling computing device of claim 12, wherein, when executed by the processor, the program instructions cause the processor to:
select a maximum first operating parameter from the plurality of first operating parameters corresponding to the monitored object with abnormal temperature if the first determination result indicates that there is a monitored object with abnormal temperature; controlling the cooling unit to gradually increase the flow rate of the coolant and/or gradually reduce the temperature of the coolant based on the maximum first operating parameter; and/or,
determine a minimum flow rate from the flow rate corresponding to the target liquid cooling sub-pipeline with abnormal flow rate if the first determination result indicates that there is a target liquid cooling sub-pipeline with abnormal flow; controlling the cooling unit to gradually increase the flow rate of the coolant based on the minimum flow rate; and/or,
determine a maximum temperature from the temperature corresponding to the target liquid cooling sub-pipeline with abnormal temperature if the first determination result indicates that there is a target liquid cooling sub-pipeline with abnormal temperature; controlling the cooling unit to gradually reduce the temperature of the coolant based on the maximum temperature.

15. The liquid cooling computing device of claim 14, wherein, when executed by the processor, the program instructions cause the processor to:
determine that the cooling unit is in an un-adjustable state and outputting first information if the flow rate after adjustment of the cooling unit does not meet a first flow condition, and/or the temperature after adjustment does not meet a first temperature condition, the first information including at least one of the monitored object with abnormal temperature, the target liquid cooling sub-pipeline with abnormal flow rate, and the/4 with abnormal temperature.

16. The liquid cooling computing device of claim 10, wherein, when executed by the processor, the program instructions cause the processor to:
receive, through the BMC of the first monitored object, second information sent by the cooling unit at a second time, the second information including a second operating parameter, a third operating parameter and a fourth operating parameter, the second operating parameter being used to indicate a pressure change of the cooling unit, the third operating parameter being used to indicate whether the cooling unit fails, and the fourth operating parameter being used to indicate the temperature of the coolant output by the cooling unit; the second time being is before the first time;
determine a second determination result to determine whether there is an abnormality in the cooling unit based on one or more of the second operating parameter, the third operating parameter, and the fourth operating parameter; and
control the cooling unit to adjust the flow rate of the coolant through the BMC of the first monitored object based on the second determination result.

17. The liquid cooling computing device of claim 16, wherein, when executed by the processor, the program instructions cause the processor to:
when the second determination result indicates that the cooling unit has abnormal pressure, control the cooling unit to gradually increase or decrease the flow rate of the coolant through the BMC of the first monitored object until the cooling unit returns to normal; and
when the second determination result indicates that the cooling unit has a temperature abnormality, control the cooling unit to gradually increase or decrease the temperature of the coolant through the BMC of the first monitored object until the cooling unit returns to normal.

18. The liquid cooling computing device of claim 17, wherein, when executed by the processor, the program instructions cause the processor to:
broadcast a third message to all monitored objects if one or more of the following conditions is met: the adjusted flow rate does not satisfy a second flow rate condition, the lowered temperature does not satisfy a second temperature condition, and the second determination result indicates that the cooling unit fails, the third message being used to instruct all the monitored objects to perform power capping or enter the low power consumption state; and
output the third message, the third message being used to indicate that the cooling unit is abnormal.

19. A liquid cooling control device comprising:
an acquisition module, the acquisition module being configured to use a baseboard management controller (BMC) of a first monitored object in a liquid cooling computing device to obtain a plurality of first operating parameters of each monitored object at a first time; and
a control module, the control module being configured to control a cooling unit in the liquid cooling computing device to adjust a flow rate and/or temperature of coolant through the BMC of the first monitored object based on the plurality of first operating parameters of each of the monitored objects.

20. The liquid cooling control device of claim 19, wherein:
the first operating parameter characterizes the temperature of the monitored object, and the monitored object includes at least one server chassis in the liquid cooling computing device and at least one server located on each server chassis, the first monitored object being one of all monitored objects.
